(19) United States
(12) Patent Application Publication
(10) Pub. No.: US 2001/0030618 A1
(43) Pub. Date: Oct. 18, 2001

(54) Analog/digital converting device and in-vehicle load current detecting device

(75) Inventors: Takeshi Endoh, Nagoya-shi (JP); Kouichi Takagi, Nagoya-shi (JP)

Correspondence Address: OLIFF & BERRIDGE, PLC, 277 S. WASHINGTON STREET, SUITE 500, ALEXANDRIA, VA, 22314, US

(73) Assignee: Autonetworks Technologies, Ltd.

(21) Appl. No.: 09/799,007

(22) Filed: Mar. 6, 2001

(30) Foreign Application Priority Data
Mar. 13, 2000 (JP) 2000-068491

(51) Int. Cl. H03M 1/10; H03M 7/00

(52) U.S. Cl. 341/120; 341/93

(57) ABSTRACT

An analog/digital converting device includes: a first constant-voltage circuit which outputs a predetermined conversion reference voltage used for analog/digital conversion; a second constant-voltage circuit which outputs a predetermined correction reference voltage used for correction of the analog/digital conversion; an analog/digital converter for converting an object analog value and a correction analog value indicative of a voltage value of the correction reference voltage into an object digital value and a correction digital value on the basis of the conversion reference voltage at a predetermined resolution; and a correction processor for previously storing a correction ideal digital value obtained by analog/digital converting a correction ideal voltage value without an error corresponding to the voltage value of the correction reference voltage on the basis of a conversion ideal voltage value without an error corresponding to the voltage value of the conversion reference voltage at the resolution, and for correcting the object digital value by multiplying the object digital value with a correction coefficient obtained by dividing the correction ideal digital value by the correction digital value.

### BACKGROUND OF THE INVENTION

1. Field of the Invention

The present invention relates to an analog/digital (hereinafter, often abbreviated to “A/D”) converting device, and an in-vehicle load current detecting device.

2. Description of the Related Art

FIG. 3 is a block diagram of an in-vehicle load current monitoring device to which an in-vehicle load current detecting device of a first conventional art is applied. The in-vehicle load current monitoring device detects the current value supplied from a battery 1 to a load 3, and, when the detected current value is an abnormal value which exceeds a predetermined reference value, interrupts the current supply from the battery 1 to the load 3. The device comprises components generally including a breaker (in this example, a PNP transistor) 5, a current detecting circuit 7, a power source circuit 9, an A/D converter 11, and a logic section 13. The A/D converter 11 and the logic section 13 are incorporated into a control CPU 15 which is formed as one chip.

The power source circuit 9 supplies a power to the CPU 15 and other components on the basis of the supply voltage from the battery 1. In this example, the power source voltage Vcc supplied from the power source circuit 9 is used also as a reference voltage (conversion reference voltage) Vref for A/D conversion of the A/D converter 11. In other words, the A/D converter 11 uses the power source voltage Vcc, also as the reference voltage Vref.

The breaker 5 is interposed in a power supply line 17 from the battery 1 to the load 3, and controlled by the logic section 13 via a breaker driving circuit 19 so as to bring the power supply line 17 into an interrupted state or an uninterrupted state. The current detecting circuit 7 detects the current value supplied from the battery 1 to the load 3, by detecting a voltage drop in a current detection resistor 21 which is interposed in the power supply line 17. The detected current value is sequentially output in the form of an analog signal. The current detecting circuit 7 is configured so as to output the detected current value as a voltage signal corresponding to the current value.

The A/D converter 11 is controlled by the logic section 13 to A/D convert the current value which is supplied from the current detecting circuit 7 via an I/O port 23 disposed in the CPU 15, by using the reference voltage Vref and at a predetermined resolution, and sequentially output the converted current value in the form of a digital value to the logic section 13.

Based on the digital current value supplied from the A/D converter 11, the logic section 13 controls the breaker 5 through the I/O port 23 and the breaker driving circuit 19, so as to open or close the breaker 5. The input current value is compared with a predetermined reference value which is previously registered. If the current value is smaller than the reference value, the breaker 5 is controlled so as to hold the state where the power supply line 17 is in an uninterrupted state, and, if the current value is larger than the reference value, the breaker 5 is controlled so as to interrupt the power supply line 17.

FIG. 4 is a block diagram of an in-vehicle load current monitoring device to which an in-vehicle load current detecting device of a second conventional art is applied. In the in-vehicle load current monitoring device, portions which are common to the device and the in-vehicle load current monitoring device shown in FIG. 3 are denoted by the same reference numerals, and their description is omitted. In the in-vehicle load current monitoring device, a reference voltage circuit 25 which is a constant voltage circuit of high accuracy that produces the reference voltage Vref on the basis of the power supplied from the battery 1 and outputs the reference voltage is disposed in addition to the power source circuit 9, and the A/D converter 11 A/D converts the current value which is detected by the current detecting circuit 7, by using the reference voltage Vref output from the reference voltage circuit 25. To comply with this, an input terminal section for receiving the reference voltage Vref output from the reference voltage circuit 25 is disposed in the CPU 15.

Although not illustrated, each of the in-vehicle load current monitoring devices of FIGS. 3 and 4 comprises a power source monitor reset IC which monitors the power source voltage Vcc that is supplied from the power source circuit 9 to the CPU 15, and which, when the power source voltage Vcc is lowered to a predetermined voltage, supplies a reset signal to the CPU 15.

However, the in-vehicle load current detecting device of the first conventional art which is used in the in-vehicle load current monitoring device of FIG. 3 has the following problem. Usually, the power source circuit 9 supplies the power to the CPU 15 and also to other circuits. Depending on the operation states of such other circuits, the power source voltage Vcc is often varied. Since the A/D converter 11 is configured so as to perform A/D conversion while using the varying power source voltage Vcc as the reference voltage Vref, there arises a problem in that the variation of the power source voltage Vcc impairs the accuracy of the A/D conversion.

In order to solve this problem, it may be contemplated to employ a method in which the power source circuit 9 is replaced with a power source circuit of a large capacity and high accuracy so that, even when the supply current is increased or decreased, the output power source voltage Vcc is hardly varied. When the power source circuit 9 is configured so as to have a large capacity and high accuracy, however, the circuit is so expensive that the cost of the device is increased therefore, this method cannot be employed.

In the in-vehicle load current detecting device of the second conventional art which is used in the in-vehicle load current monitoring device of FIG. 4, the reference voltage circuit 25 of high accuracy is disposed in addition to the power source circuit 9. Therefore, A/D conversion can be performed without being affected by variations of the power source voltage Vcc. However, it is impossible even for the reference voltage circuit 25 of high accuracy to completely suppress variations of the reference voltage Vref, thereby producing a problem in that an error of A/D conversion due to variations of the reference voltage Vref cannot be eliminated. From the viewpoint of the cost and the like, also the improvement of the accuracy of the reference voltage circuit 25 is limited.

In the in-vehicle load current detecting device of the second conventional art, in order to A/D convert the analog voltage signal which is output from the current detecting circuit 7 and indicative of the current value, the reference voltage Vref must have a level which is higher than that of the input voltage signal which is to be A/D converted. Therefore, the reference voltage Vref tends to become higher. When the reference voltage circuit 25 is configured so as to output of the reference voltage Vref of a high level, the reference voltage circuit 25 becomes bulky and complicated, thereby producing a problem in that the cost of the device is increased.

### SUMMARY OF THE INVENTION

The invention has been made to solve the above-discussed problems, and therefore an object of the invention is to provide an analog/digital converting device and an in-vehicle load current detecting device in which an error of A/D conversion due to variations of a conversion reference voltage used for A/D conversion can be suppressed by a low-cost configuration.

To achieve the above object, according to a first aspect of the invention, there is provided an analog/digital converting device, comprising: a first constant-voltage circuit which outputs a predetermined conversion reference voltage that is used for analog/digital conversion; a second constant-voltage circuit which outputs a predetermined correction reference voltage that is used for correction of the analog/digital conversion; analog/digital converting means for analog/digital converting an object analog value which is input to be converted, and a correction analog value indicative of a voltage value of the correction reference voltage, by using the conversion reference voltage and at a predetermined resolution, and for outputting obtained digital values as an object digital value and a correction digital value, respectively; and correction processing means for previously storing a correction ideal digital value which is obtained by analog/digital converting a correction ideal voltage value which does not contain an error corresponding to the voltage value of the correction reference voltage, by using a conversion ideal voltage value which does not contain an error corresponding to the voltage value of the conversion reference voltage, and at the resolution, and for correcting the object digital value which is supplied from the analog/digital converting means, by multiplying the object digital value with a correction coefficient that is obtained by dividing the correction ideal digital value by the correction digital value supplied from the analog/digital converting means.

Preferably, the first constant-voltage circuit is a power source circuit which powers the analog/digital converting means and the correction processing means by a predetermined power source voltage, and the power source voltage which is supplied from the power source circuit to the analog/digital converting means is used as the conversion reference voltage.

Preferably, a correcting function of the correction processing means is performed by a microcomputer, and a voltage supplying function of the second constant-voltage circuit by which the correction reference voltage is supplied is performed by a constant-voltage supplying section of a power source monitor reset IC having: a power source monitoring section which monitors the power source voltage that is supplied from the power source circuit to the microcomputer, and which, when the power source voltage is lowered to a predetermined voltage, supplies a reset signal to the microcomputer; and the constant-voltage supplying section which supplies the correction reference voltage.

Also, according to a second aspect of the invention, in the in-vehicle load current detecting device which comprises an analog/digital converting device according to the first aspect, and which detects a current value supplied to a load mounted on a vehicle, as a digital value, wherein the detecting device comprises: an analog/digital converting device according to the first aspect; and current detecting means for detecting the current value supplied to the load, and for supplying the detected current value to the analog/digital converting means of the analog/digital converting device, as the object analog value.

### BRIEF DESCRIPTION OF THE DRAWINGS

FIG. 1 is a block diagram of an in-vehicle load current monitoring device to which an A/D converting device and an in-vehicle load current detecting device of a first embodiment of the invention are applied.

FIG. 2 is a block diagram of an in-vehicle load current monitoring device to which an A/D converting device and an in-vehicle load current detecting device of a second embodiment of the invention are applied.

FIG. 3 is a block diagram of an in-vehicle load current monitoring device to which an in-vehicle load current detecting device of a first conventional art is applied.

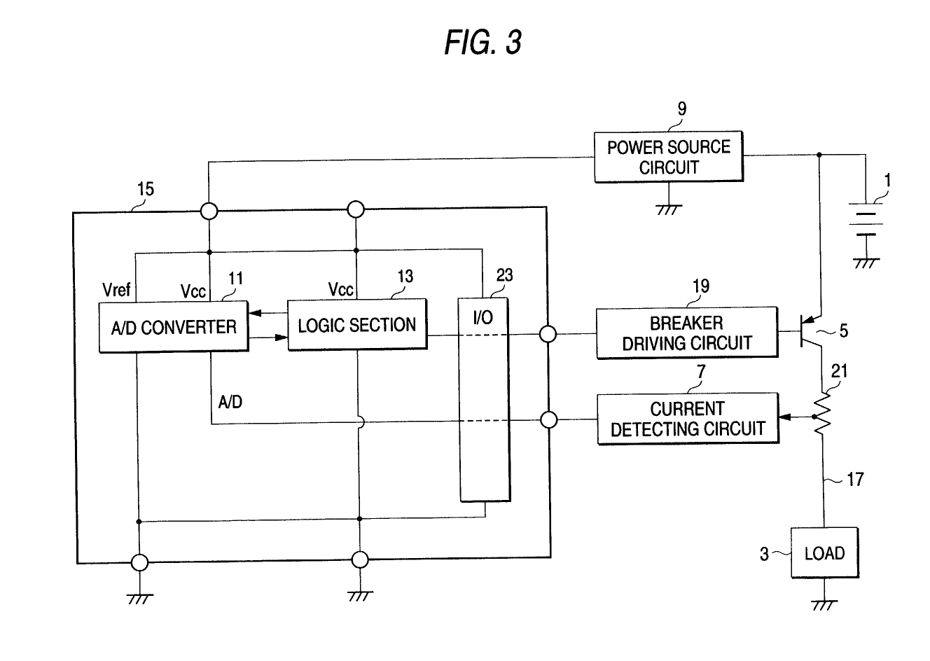

FIG. 4 is a block diagram of an in-vehicle load current monitoring device to which an in-vehicle load current detecting device of a second conventional art is applied.

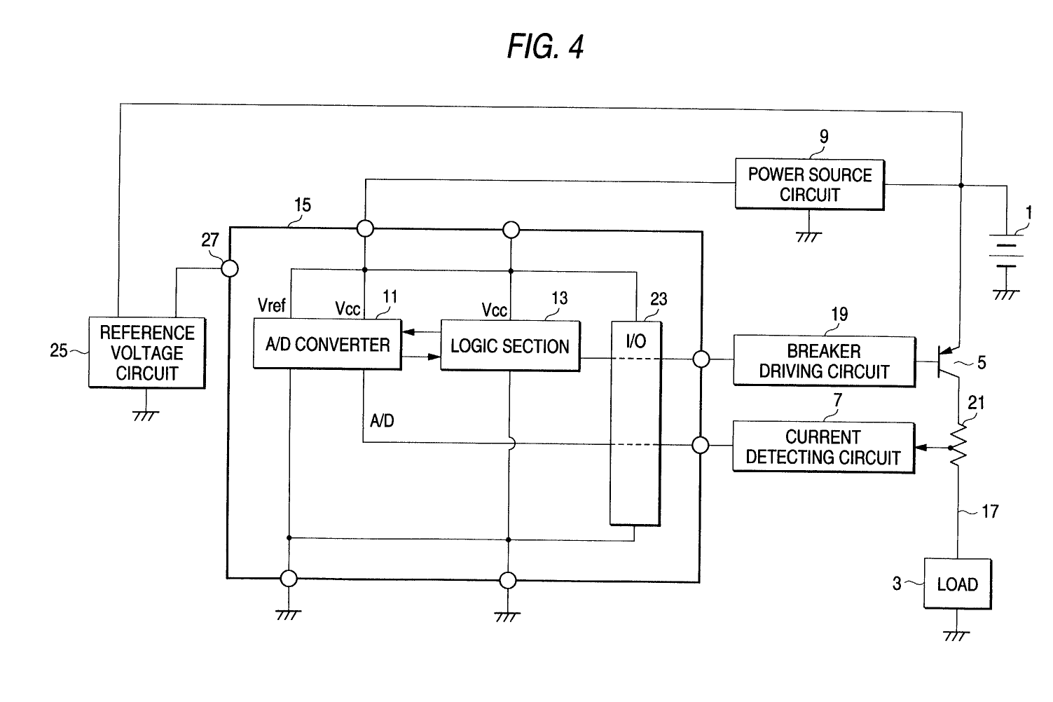

### DETAILED DESCRIPTION OF THE PREFERRED EMBODIMENTS

Now, a description will be given in more detail of preferred embodiments of the invention with reference to the accompanying drawings.

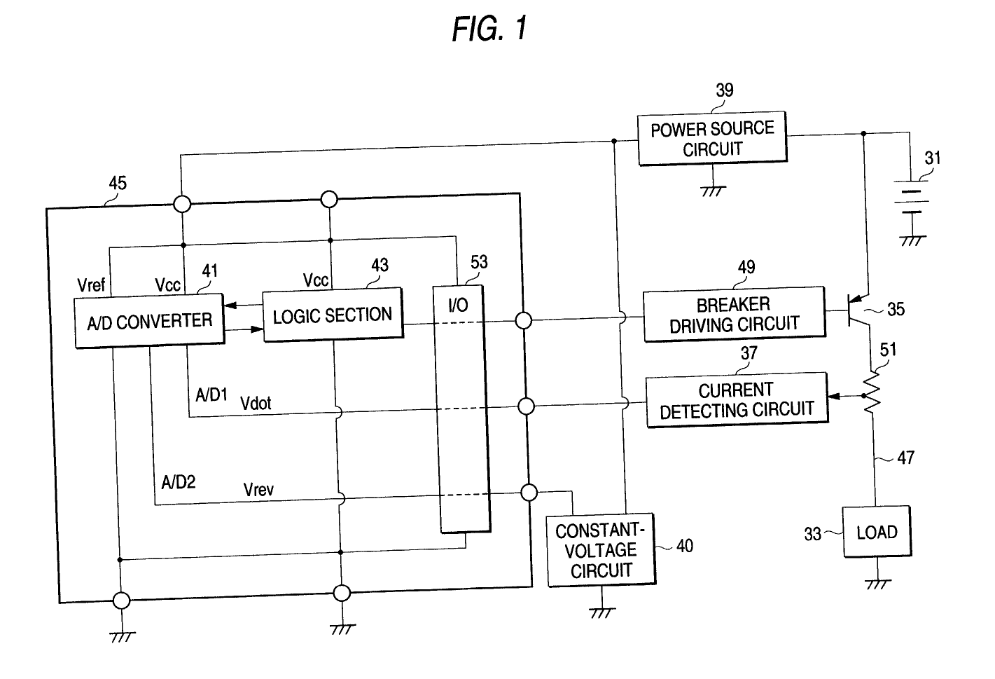

FIG. 1 is a block diagram of an in-vehicle load current monitoring device to which an A/D converting device and an in-vehicle load current detecting device of a first embodiment of the invention are applied. The in-vehicle load current monitoring device detects the current value supplied from a battery 31 to a load 33, and, when the detected current value is an abnormal value which exceeds a predetermined reference value, interrupts the current supply from the battery 31 to the load 33. The device comprises components generally including a breaker (in the embodiment, a PNP transistor) 35, a current detecting circuit 37, a power source circuit (first constant-voltage circuit) 39, a constant-voltage circuit (second constant-voltage circuit) 40, an A/D converter (A/D converting means) 41, and a logic section (correction processing means) 43. The A/D converter 41 and the logic section 43 are incorporated into a control CPU (microcomputer) 45 which is formed as one chip.

The power source circuit 39 supplies a power to the CPU 45 and other components on the basis of the supply voltage from the battery 31. In the embodiment, the power source voltage Vcc supplied from the power source circuit 39 is used also as a conversion reference voltage Vref for A/D conversion of the A/D converter 41. In other words, the A/D converter 41 uses the power source voltage Vcc, also as the reference voltage Vref.

The constant-voltage circuit 40 receives the power supply from the power source circuit 39, and stably and accurately outputs a correction reference voltage Vrev of a predetermined value which is to be used for correction of the A/D conversion of the A/D converter 41.

The breaker 35 is interposed in a power supply line 47 from the battery 31 to the load 33, and controlled via a breaker driving circuit 49 so as to be turned on or off in accordance with instructions from the logic section 43, thereby bringing the power supply line 47 into an interrupted state or an uninterrupted state. In the embodiment, the base potential of the transistor serving as the breaker 35 is switched by the breaker driving circuit 49 to be low or high, whereby the transistor is turned on or off so that the power supply line 47 is brought into an uninterrupted state or an interrupted state.

The current detecting circuit 37 detects the current value supplied from the battery 31 to the load 33, on the basis of a voltage drop in a current detection resistor 51 which is interposed in the power supply line 47, and sequentially outputs an analog voltage signal of a voltage level according to the detected current value. The voltage value of the voltage signal is indicated by Vdet.

The A/D converter 41 is controlled by the logic section 43 to rapidly alternately A/D convert the voltage value (object analog value) Vdet of the voltage signal, and the correction reference voltage (correction analog value) Vrev which are supplied via an I/O port 53 disposed in the CPU 45 from the current detecting circuit 37 and the constant-voltage circuit 40, respectively, by using the power source voltage Vcc supplied from the power source circuit 39 as the reference voltage Vref and at a predetermined resolution, and sequentially output the converted current values in the form of digital values to the logic section 43. The digital value (object digital value) which is obtained by digital converting the voltage value Vdet of the voltage signal is indicated by Ddet, and the digital value (correction digital value) which is obtained by digital converting the correction reference voltage Vrev is indicated by Drev.

The logic section 43 has an A/D converter controlling function for the A/D converter 41, a breaker controlling function of controlling the breaker 35 on the basis of the detected current value, and a correction processing function of correcting the voltage value Ddet which has been A/D converted by the A/D converter 41.

As for the A/D converter controlling function, the logic section 43 controls the A/D converter 41 so as to rapidly alternately A/D convert the voltage value Vdet of the voltage signal and the correction reference voltage Vrev, by using the power source voltage Vcc as the reference voltage Vref and at the predetermined resolution as described above.

As for the correction processing function, the logic section 43 previously stores a correction ideal digital value Krev which is obtained by A/D converting a correction ideal reference voltage (correction ideal voltage value) Vrevtyp which does not contain an error of the voltage value Vrev of the correction reference voltage, by using a conversion ideal reference voltage (conversion ideal voltage value) Vcctyp which does not contain an error of the voltage value Vcc of the power source voltage serving as the conversion reference voltage Vref, and at the same resolution as that of the A/D converter 41. The logic section 43 sequentially obtains a corrected value Ddet′ of the voltage value Ddet of the A/D-converted voltage signal, by sequentially multiplying the voltage value Ddet of the A/D-converted voltage signal supplied from the A/D converter 41, with a correction coefficient κ that is obtained by sequentially dividing the correction ideal digital value Krev by the A/D-converted correction reference voltage Drev supplied from the A/D converter 41. This function will be described later in detail.

As for the breaker controlling function, the logic section 43 recognizes the current value which is detected by the current detecting circuit 37 and supplied to the load 33, in accordance with a preset conversion formula on the basis of the voltage value Ddet′ of the voltage signal that is corrected by the correction processing function, and sequentially monitors the current value. The logic section 43 compares the recognized current value with a predetermined reference value which is previously registered, and, if the recognized current value is smaller than the reference value, controls the breaker 35 so as to hold the state where the power supply line 47 is in an uninterrupted state, and, if the recognized current value is larger than the reference value, controls the breaker 35 so as to interrupt the power supply line 47.

Although not illustrated, the in-vehicle load current monitoring device comprises a power source monitor reset IC which monitors the power source voltage Vcc that is supplied from the power source circuit 39 to the CPU 45, and which, when the power source voltage Vcc is lowered to a predetermined voltage, supplies a reset signal to the logic section 43 of the CPU 45. When the reset signal is input, the logic section 43 initializes the operation.

Next, the correction process which is performed by the logic section 43 will be described.

The A/D conversions of the voltage value Vdet of the voltage signal, and the correction reference voltage Vrev which are performed by the A/D converter 41 are indicated by the following expressions, respectively. In the following expressions, Rs is the division number in each of the A/D conversions, and the value which is obtained by dividing the conversion reference voltage Vref (in the embodiment, the power source voltage Vcc) by the division number Rs equals to the division resolution. The symbol int[ ] means that the value in [ ] is converted to an integer by rounding the value to the nearest integer.

$$\begin{matrix}D det = int [ \frac{Vdet}{Vcc} Rs ] & ( Ex . 1 ) \\ Drev = int [ \frac{Vrec}{Vcc} Rs ] & ( Ex . 2 )\end{matrix}$$

The principle of the A/D conversions by conversion formulae of Exs. (1) and (2) above will be briefly described by illustrating the case of Ex. (1) as an example. In the A/D conversion shown in Ex. (1), the region from zero to Vcc corresponding to the power source voltage Vcc is divided by the division number Rs. Plural subregions which are obtained as a result of the division are numbered individually from zero to Rs in ascending order. The number assigned to the subregion to which the voltage value Vdet of the voltage signal belongs is given as the A/D converted value of the voltage value Vdet.

Ideally speaking, the conversion reference voltage Vref (in the embodiment, the power source voltage Vcc) is held to a constant value (ideal value Vcctyp). Actually, an erroneous variation from the ideal value Vcctyp is caused by variations of the current value supplied from the power source circuit 39 and other factors, and hence an error due to the erroneous is produced in the A/D conversion by the erroneous variation.

Therefore, the principal object of the A/D converting device and the in-vehicle load current detecting device of the embodiment is to correct an error in the A/D conversion of the object analog value (in the embodiment, the voltage value Vdet of the voltage signal) which is to be converted, due to an erroneous variation of the conversion reference voltage Vref (in the embodiment, the power source voltage Vcc).

The relationship between the power source voltage Vcc and the ideal power source voltage Vcctyp is indicated by using an error rate a as follows:

Vcc=Vcctyp(1+α) (Ex. 3)

Similarly, also the correction reference voltage Vrev output from the constant-voltage circuit 40 actually has an erroneous variation to the predetermined ideal value (correction ideal reference voltage) Vrevtyp. When the error rate of the correction reference voltage is indicated by β, the relationship between the correction reference voltage Vrev and the correction ideal reference voltage Vrevtyp is indicated by using the error rate β as follows:

Vrev=Vrevtyp(1+α) (Ex. 4)

The correction ideal digital value Krev which is obtained by A/D converting the correction ideal reference voltage Vrevtyp at the division number Rs by using the ideal power source voltage Vcctyp is given as follows:

$$Krev = int [ \frac{Vrevtyp}{Vcctyp} Rs ] \qquad ( Ex . 5 )$$

Therefore, the correction coefficient κ which is calculated by the correction process of the logic section 43 is approximately indicated by using Exs. (2) to (5) in the following manner:

$$\begin{matrix}κ = Krev / Drev \\ = \{ int [ \frac{Vrevtyp}{Vcctyp} Rs ] \} / \{ int [ \frac{Vrevtyp ( 1 + β )}{Vcctyp ( 1 + α )} Rs ] \} \\ \approx \{ \frac{Vrevtyp}{Vcctyp} Rs \} / \{ \frac{Vrevtyp ( 1 + β )}{Vcctyp ( 1 + α )} Rs \} \\ = \frac{1 + α}{1 + β}\end{matrix} \qquad ( Ex . 6 )$$

Furthermore, the voltage value Ddet′ which is obtained as a result of performing correction on the voltage value Ddet of the A/D-converted voltage signal by the correction process of the logic section 43 is approximately indicated by using Exs. (1), (2), and (6) in the following manner:

$$\begin{matrix}{Ddet}^{′} = Ddet \cdot \frac{Krev}{Drev} \\ \approx int [ \frac{Vdet}{Vcctyp ( 1 + α )} Rs ] \cdot \frac{1 + α}{1 + β} \\ \approx \{ \frac{Vdet}{Vcctyp ( 1 + α )} Rs \} 1 + \frac{α}{1 + β} \\ = \{ \frac{Vdet}{Vcctyp} Rs \} \frac{1}{1 + β}\end{matrix} \qquad ( Ex . 7 )$$

An ideal A/D-converted value Ddet″ which is obtained by A/D converting the voltage value Vdet of the voltage signal by using the ideal power source voltage Vcctyp having no error, and at a resolution corresponding to the division number Rs is given as follows:

$${Ddet}^{″} = int [ \frac{Vdet}{Vcctyp} Rs ] \qquad ( Ex . 8 )$$

Using the ideal A/D-converted value Ddet″ of Ex. (8), the corrected voltage value Ddet′ indicated by Ex. (7) is approximately expressed as follows:

$$\begin{matrix}{Ddet}^{′} \approx {Ddet}^{″} \cdot \frac{1}{1 + β} \\ = {Ddet}^{″} \cdot \{ 1 - \frac{β}{1 + β} \}\end{matrix} \qquad ( Ex . 9 )$$

The relationship between the uncorrected voltage value Ddet and the ideal A/D-converted value Ddet″ is approximately indicated by using Exs. (1), (3), and (8) in the following manner:

$$\begin{matrix}Ddet \approx {Ddet}^{″} \cdot \frac{1}{1 + α} \\ = {Ddet}^{″} \cdot \{ 1 - \frac{α}{1 + α} \}\end{matrix} \qquad ( Ex . 10 )$$

Therefore, the following will be seen from Exs. (9) and (10). When the error rate β of the correction reference voltage Vrev to the correction ideal reference voltage Vrevtyp satisfies the following relationship with respect to the error rate α of the power source voltage Vcc to the ideal power source voltage Vcctyp, the conversion accuracy of the A/D conversion of the voltage value Vdet can be improved by the correction process of the embodiment.

$$\vert \frac{β}{1 + β} \vert < \vert \frac{α}{1 + α} \vert \qquad ( Ex . 11 )$$

The principle of the correction in which an error of the voltage value Ddet due to an erroneous variation of the power source voltage Vcc serving as the conversion reference voltage Vref is corrected by multiplying the A/D-converted voltage value Ddet with the correction coefficient κ will be briefly described. For the sake of simplicity, it is assumed that the value of β is substantially zero. In the case where the power source voltage Vcc is varied in a direction along which the voltage becomes higher than the ideal power source voltage Vcctyp, for example, the voltage value Ddet is accordingly varied in a direction along which the value becomes smaller than the ideal digital value Ddet″. In this case, similarly, also the A/D-converted correction reference voltage Drev is varied in a direction along which the voltage becomes smaller than the correction ideal digital value Krev. At this time, the correction ideal digital value Krev is constant. Consequently, the correction coefficient κ which is obtained by dividing Krev by Drev is varied in a direction along which the coefficient becomes larger than 1. When the voltage value Ddet is multiplied by the correction coefficient κ, therefore, the variations of the correction coefficient κ and the voltage value Ddet which are caused by variations of the power source voltage Vcc are substantially cancelled.

The voltage value Vdet and the correction reference voltage Vrev are rapidly alternately A/D converted by the A/D converter 41. At each timing, therefore, the voltage value Vdet and the correction reference voltage Vrev are A/D converted by the substantially same conversion reference voltage Vref (in this embodiment, the power source voltage Vcc). As a result, the A/D-converted voltage value Ddet and correction reference voltage Drev are affected by a substantially same erroneous variation of the power source voltage Vcc.

Hereinafter, a specific example of the correction process in the case where Vcctyp=5 volts, α=0.1, Vcc=5(1-0.1) volts (in this case, an erroneous variation toward the minus side will be considered), Vdet=1 volt, Rs=255 (8 bits), Vrevtyp=2 volts, β=0.05, Vrev=2(1-0.05) volts (in this case, an erroneous variation toward the minus side will be considered) will be described.

In this case, Ddet, Drev, and Krev are given as follows:

$$\begin{matrix}Ddet = int [ \frac{1}{5 ( 1 - 0.1 )} \cdot 255 ] = 57 \\ Drev = int [ \frac{2 ( 1 - 0.05 )}{5 ( 1 - 0.1 )} \cdot 255 ] = 108 \\ Krev = int [ \frac{2}{5} \cdot 255 ] = 102\end{matrix} \qquad ( Ex . 12 )$$

When the above-mentioned correction process is performed on Ddet, the following is attained:

$${Ddet}^{′} = 57 \cdot \frac{102}{108} \approx 53.83 \qquad ( Ex . 13 )$$

In the above expression, also the decimal places are calculated because the correction calculation is performed in the logic section 43.

By contrast, the ideal digital converted value Ddet″ is given as follows:

$$D {det}^{″} = int [ \frac{1}{5} \cdot 255 ] = 51 \qquad ( Ex . 14 )$$

From the above expressions, the error rates of the uncorrected voltage value Ddet and the corrected voltage value Ddet′ with respect to the ideal digital converted value Ddet″ are calculated in the followings manner:

$$\frac{Ddet - {Ddet}^{″}}{{Ddet}^{″}} = \frac{57 - 51}{51} \approx 11.7 \% \\ \frac{{Ddet}^{′} - {Ddet}^{″}}{{Ddet}^{″}} = \frac{53.83 - 51}{51} \approx 5.5 \% \qquad ( Ex . 15 )$$

As a result of the correction process of the embodiment, in this specific example, the accuracy is improved by about 5%.

According to this configuration, in the in-vehicle load current monitoring device, as described above, an error in the A/D conversion of the voltage value Vdet of the voltage signal which is caused by variations of the conversion reference voltage Vref (in the embodiment, the power source voltage Vcc) that is used for the A/D conversion is effectively suppressed by the above-mentioned correction process. Consequently, the current value supplied to the load 33 is accurately detected as a digital value on the basis of the voltage value Ddet′ which is a corrected digital value of the voltage value.

When an abnormal current exceeding the predetermined reference value flows through the load 33, therefore, the abnormal current can be correctly detected, so that the power supply line 47 can be interrupted by the breaker 35.

As described above, according to the embodiment, on the basis of the voltage value Ddet and the correction reference voltage Drev which are digital values that are obtained in the A/D converter 41 by rapidly alternately A/D converting the voltage value Vdet of the voltage signal indicative of the detected current value, and the correction reference voltage Vrev, by using the power source voltage Vcc as the conversion reference voltage Vref, and at a resolution corresponding to the predetermined division number Rs, the voltage value Ddet is corrected by multiplying the voltage value Ddet by the correction coefficient κ which is obtained by dividing the correction ideal digital value Krev which does not contain an error due to variations of the correction reference voltage Vref (in the embodiment, Vcc), and which is previously stored, by the correction reference voltage Drev. Consequently, an error of the voltage value Ddet which is caused in the A/D conversion due to variations of the power source voltage Vcc serving as the conversion reference voltage Vref can be suppressed. According to this configuration, even when the power source circuit 39 for supplying the power source voltage Vcc is not configured by a circuit which is expensive and accurate, the voltage value Vdet which is the conversion object can be accurately A/D converted. Therefore, the accuracy of the A/D conversion can be improved, and the current value supplied to the load 33 can be accurately monitored, while the power source circuit 39 is configured by a simple one so as to reduce the cost of the device configuration.

Preferably, the constant-voltage circuit 40 for outputting the correction reference voltage Vrev is configured by a circuit of high accuracy. However, the constant-voltage circuit may be realized at a low cost by a circuit configuration which is relatively small in size and simple, because the correction reference voltage Vrev can be lower than the conversion reference voltage Vref. Therefore, the device can be configured at a lower cost than the second conventional art in which a reference voltage circuit of a high output voltage is used.

Since the power source voltage Vcc output from the power source circuit 39 is used also as the conversion reference voltage Vref for the A/D conversion, it is not necessary to dispose a dedicated constant-voltage circuit for generating the conversion reference voltage Vref, and hence the cost of the device configuration can be reduced.

Since the configuration in which the power source voltage Vcc is used also as the conversion reference voltage Vref is employed, unlike the second conventional art, the CPU 45 which is formed as one chip is not required to comprise an input terminal section for inputting the conversion reference voltage, so that the configuration of the CPU 45 can be simplified and the cost can be reduced. In the embodiment, the correction reference voltage Vrev is additionally input to the CPU 45. The correction reference voltage Vrev is input to the A/D conversion input terminal section to which the signal that is the A/D conversion object is to be input. Usually, the CPU 45 of this kind is provided with plural (for example, eight) A/D conversion input terminal sections. Therefore, the configuration of the CPU 45 is not substantially complicated by the input of the correction reference voltage Vrev.

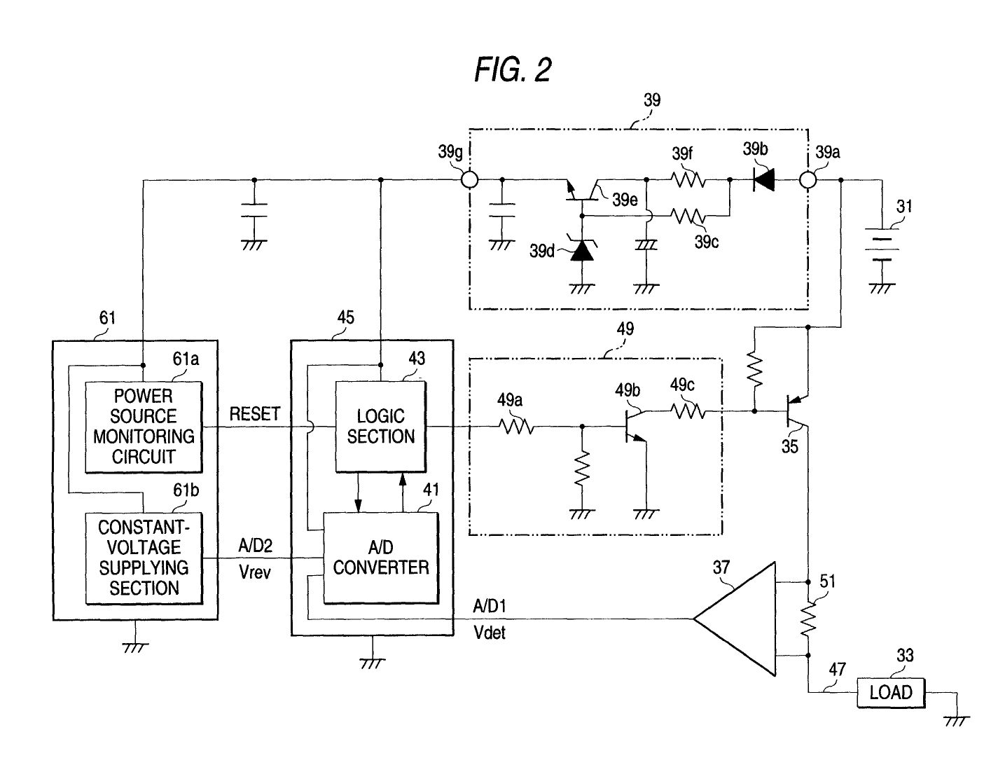

FIG. 2 is a block diagram of an in-vehicle load current monitoring device to which an A/D converting device and an in-vehicle load current detecting device of a second embodiment of the invention are applied. The in-vehicle load current monitoring device in the embodiment is substantially different from the above-described in-vehicle load current monitoring device in the first embodiment, only in that a constant-voltage supplying section 61b of a power source monitor reset IC 61 is used as the constant-voltage circuit 40, and that the power source circuit 39 and the breaker driving circuit 49 are configured in a more specific manner. The corresponding portions are denoted by the same reference numerals, and their description is omitted. In FIG. 2, for the sake of convenience, the I/O port 53 is not illustrated in the configuration of the CPU 45.

The power source monitor reset IC 61 is usually disposed in a conventional in-vehicle load current monitoring device of this kind, and comprises components including a power source monitoring section 61a and the constant-voltage supplying section 61b. The power source monitoring section 61a monitors the power source voltage Vcc which is supplied from the power source circuit 39 to the CPU 45, and, when the power source voltage Vcc is lowered to a predetermined voltage, supplies a reset signal to the CPU 45. The constant-voltage supplying section 61b is powered by the power source circuit 39, and has a function of accurately stably supplying a constant voltage. In the embodiment, the constant voltage output from the constant-voltage supplying section 61b is used as the correction reference voltage Vrev.

In the power source circuit 39, the power source voltage is stabilized in the following manner. When the battery voltage which is supplied from the battery 31 via an input terminal section 39a and a reverse blocking diode 39b becomes higher than a predetermined voltage value, the reverse current of a Zener diode 39d which flows from the diode 39b to the ground via a resistor 39c and the Zener diode 39d is increased. In accordance with this increase, the base current which flows from the diode 39b to the base of an NPN transistor 39e via the resistor 39c is reduced. This causes the output voltage which is applied to an output terminal section 39g via the diode 39b, a resistor 39f, and the transistor 39e, to be lowered. As a result, the output voltage is prevented from being raised in accordance with the rise of the battery voltage.

By contrast, when the battery voltage becomes lower than the predetermined voltage value, the reverse current of the Zener diode 39d is decreased, and, in accordance with this decrease, the base current of the transistor 39e is increased. This causes the output voltage which is applied to the output terminal section 39g to be raised. As a result, the lowering of the output voltage which advances in accordance with that of the battery voltage is suppressed.

In the breaker driving circuit 49, when the control signal which is applied from the logic section 43 to the base of an NPN transistor 49b via a resistor 49a is high, the transistor 49b is turned on, and the base potential of the transistor 35 serving as the breaker 35 is lowered so that also the transistor 35 is turned on, thereby bringing the power supply line 47 into an uninterrupted state. By contrast, when the control signal which is applied from the logic section 43 to the base of the transistor 49b is low, the transistor 49b is turned off, and hence the base potential of the transistor 35 is raised so that also the transistor 35 is turned off, thereby interrupting the power supply line 47.

As described above, according to the embodiment, the same effects as those of the first embodiment can be attained. Since the constant voltage output from the constant-voltage supplying section 61b of the power source monitor reset IC 61 is used as the correction reference voltage Vrev, moreover, the correction reference voltage Vrev can be obtained by a configuration of a low cost without adding further components.

According to the first aspect of the invention, on the basis of the object digital value and the correction digital value which are obtained in the analog/digital converting means by analog/digital converting the object analog value and the correction analog value, by using the conversion reference voltage and at a predetermined resolution, the object digital value is corrected by multiplying the object digital value with the correction coefficient that is obtained by dividing the correction ideal digital value which is previously recorded, and which does not contain an error due to variations of the correction reference voltage, by the correction digital value. Therefore, an error of the object digital value which is caused in the analog/digital conversion due to variations of the conversion reference voltage can be suppressed. According to this configuration, even when the first constant-voltage circuit for supplying the conversion reference voltage is not configured by a circuit which is expensive and accurate, the object analog value can be accurately analog/digital converted, and the accuracy of the analog/digital conversion can be improved while the first constant-voltage circuit is configured by a simple one so as to reduce the cost of the device configuration.

Although the second constant-voltage circuit for outputting the correction reference voltage is preferably configured by a circuit of high accuracy, the circuit may be realized at a low cost by a circuit configuration which is relatively small in size and simple, because the correction reference voltage can be lower than the conversion reference voltage. Therefore, the analog/digital converting device can be configured at a lower cost than the second conventional art in which a reference voltage circuit of a high output voltage is used.

According to the second aspect of the invention, the power source voltage which is supplied from the power source circuit to the analog/digital converting means and the correction processing means is used as the conversion reference voltage of the analog/digital conversion. Therefore, it is not necessary to dispose a dedicated constant-voltage circuit for generating the conversion reference voltage, and hence the cost of the device configuration can be reduced.

Usually, a conventional analog/digital converting device comprises a power source monitor reset IC which monitors the power source voltage supplied to a microcomputer that is disposed in the analog/digital converting device. Such a power source monitor reset IC is often provided with a constant-voltage supplying section for outputting a predetermined constant voltage. According to the third aspect of the invention, the constant voltage output from the constant-voltage supplying section of the power source monitor reset IC is used as the correction reference voltage. Therefore, the correction reference voltage can be obtained by a configuration of a low cost without adding further components.

According to the fourth aspect of the invention, a current value supplied to a load can be accurately detected as a digital value by a configuration of a low cost, while suppressing an error of the analog/digital conversion due to variations of the conversion reference voltage that is used in the analog/digital conversion.

What is claimed is:

1. An analog/digital converting device comprising:
a first constant-voltage circuit which outputs a predetermined conversion reference voltage used for analog/digital conversion;
a second constant-voltage circuit which outputs a predetermined correction reference voltage used for correction of the analog/digital conversion;
an analog/digital converter for converting an object analog value and a correction analog value indicative of a voltage value of the correction reference voltage into an object digital value and a correction digital value on the basis of the conversion reference voltage at a predetermined resolution; and
a correction processor for previously storing a correction ideal digital value obtained by analog/digital converting a correction ideal voltage value without an error corresponding to the voltage value of the correction reference voltage on the basis of a conversion ideal voltage value without an error corresponding to the voltage value of the conversion reference voltage at the resolution, and for correcting the object digital value by multiplying the object digital value with a correction coefficient obtained by dividing the correction ideal digital value by the correction digital value.

2. The analog/digital converting device according to claim 1, wherein said first constant-voltage circuit is a power source circuit which powers said analog/digital converter and said correction processor by a predetermined power source voltage; and
wherein the power source voltage supplied from said power source circuit to said analog/digital converter is used as the conversion reference voltage.

3. The analog/digital converting device according to claim 2, wherein
said correction processor comprises a microcomputer; and
a voltage supplying function of said second constant-voltage circuit by which the correction reference voltage is supplied is performed by a constant-voltage supplying section of a power source monitor reset IC having: a power source monitoring section which monitors the power source voltage that is supplied from said power source circuit to said microcomputer, and which, when the power source voltage is lowered to a predetermined voltage, supplies a reset signal to said microcomputer; and said constant-voltage supplying section which supplies the correction reference voltage.

4. An in-vehicle load current detecting device which comprises an analog/digital converting device according to any one of claims 1 to 3, and which detects a current value supplied to a load mounted on a vehicle, as a digital value, wherein
said detecting device comprises:
an analog/digital converting device according to any one of claims 1 to 3; and
a current detector for detecting the current value supplied to the load, and for supplying the detected current value to said analog/digital converter of said analog/digital converting device, as the object analog value.
